(19) United States
(12) Patent Application Publication
(10) Pub. No.: US 2024/0347406 A1
(43) Pub. Date: Oct. 17, 2024

(54) PACKAGE STRUCTURE AND MEMORY SYSTEM

(71) Applicant: YANGTZE MEMORY TECHNOLOGIES CO., LTD., Wuhan (CN)

(72) Inventors: Shanshan ZHAO, Wuhan (CN); Baohua ZHANG, Wuhan (CN); Li TAO, Wuhan (CN)

(21) Appl. No.: 18/364,301

(22) Filed: Aug. 2, 2023

(30) Foreign Application Priority Data
Apr. 12, 2023 (CN) 2023103977883

(51) Int. Cl. H01L 23/31; H01L 21/56; H01L 25/18; H10B 80/00

(52) U.S. Cl. CPC H01L 23/3135; H01L 21/56; H01L 23/3121; H01L 25/18; H10B 80/00; H01L 23/295

(57) ABSTRACT

The present disclosure provides a package structure and its forming method, a memory system and its forming method. The package structure includes: a plastic encapsulation layer and a rib like structure, wherein, the rib like structure is located on the plastic encapsulation layer, and a bottom surface of the rib like structure is located on a top surface of the plastic encapsulation layer.

### CROSS-REFERENCE TO RELATED APPLICATIONS

The present application claims priority to Chinese Patent Application No. 2023103977883, which was filed Apr. 12, 2023, is titled “A PACKAGE STRUCTURE AND ITS FORMING METHOD, A MEMORY SYSTEM AND ITS FORMING METHOD,” and is hereby incorporated herein by reference in its entirety.

### TECHNICAL FIELD

The present disclosure relates to the field of semiconductor technology, in particular to a package structure and a forming method thereof, a memory system and a forming method thereof.

### BACKGROUND

Semiconductor devices include a plastic encapsulation body, a semiconductor chip, a substrate and a solder ball. In practical applications, when the ambient temperature changes dramatically, the plastic encapsulation body is easy to warp and deform, resulting in the failure of semiconductor devices. When the semiconductor device is in a high power work state, the semiconductor device is prone to thermal failure.

### SUMMARY

Examples of the present disclosure provides a package structure and a forming method thereof, a memory system and a forming method thereof for solving various challenges.

In the first aspect, the example of the present disclosure provides a package structure including a plastic encapsulation layer and a rib like structure, wherein the rib like structure is located on the plastic encapsulation layer, and a bottom surface of the rib like structure is located on a top surface of the plastic encapsulation layer.

In an example, the rib like structure includes a rib like portion and a hollow portion, a bottom surface of the rib like portion is located on the top surface of the plastic encapsulation layer, and the hollow portion exposes the top surface of the plastic encapsulation layer.

In an example, the rib like portion includes a plurality of portions extending along a first direction and a plurality of portions extending along a second direction, the first direction intersects the second direction, and both are perpendicular to the thickness direction of the rib like structure.

In an example, a material of the rib like structure is the same as that of the plastic encapsulation layer.

In an example, a material of the rib like structure is different from that of the plastic encapsulation layer.

In an example, a thermal expansion coefficient of a material of the rib like structure is less than that of a material of the plastic encapsulation layer.

In an example, a thermal expansion coefficient of a material of the plastic encapsulation layer ranges from 9 ppm/K to 36 ppm/K, and a thermal expansion coefficient of a material of the rib like structure ranges from 0.12 ppm/K to 0.18 ppm/K.

In an example, a thermal conductivity of a material of the rib like structure is greater than a preset value.

In an example, the preset value is 200 W/(m·K).

In the second aspect, the example of the present disclosure provides a memory system including a package substrate, a chip, a plastic encapsulation layer and a rib like structure, wherein the chip is located on the package substrate; the plastic encapsulation layer covers the chip; the rib like structure is located on the plastic encapsulation layer, and a bottom surface of the rib like structure is located on a top surface of the plastic encapsulation layer.

In an example, the rib like structure includes a rib like portion and a hollow portion, a bottom surface of the rib like portion is located on the top surface of the plastic encapsulation layer, and the hollow portion exposes the top surface of the plastic encapsulation layer.

In an example, the chip includes a memory chip and a controller chip arranged in a direction parallel to the package substrate; a ratio of an area of an orthographic projection of the rib like portion directly above the controller chip on the package substrate to an area of an orthographic projection of the rib like structure directly above the controller chip on the package substrate is a first ratio; a ratio of an area of an orthographic projection of the rib like portion directly above the memory chip on the package substrate to an area of an orthographic projection of the rib like structure directly above the memory chip on the package substrate is a second ratio; the first ratio is greater than or equal to the second ratio.

In an example, the memory chip includes a three-dimensional (3D) NAND memory chip.

In the third aspect, the example of the present disclosure provides a forming method of a package structure including: forming a plastic encapsulation layer; forming a rib like structure on the plastic encapsulation layer, a bottom surface of the rib like structure being located on a top surface of the plastic encapsulation layer.

In an example, the rib like structure includes a rib like portion and a hollow portion, a bottom surface of the rib like portion is located on the top surface of the plastic encapsulation layer, and the hollow portion exposes the top surface of the plastic encapsulation layer.

In an example, the rib like portion includes a plurality of portions extending along a first direction and a plurality of portions extending along a second direction, the first direction intersects the second direction, and both are perpendicular to the thickness direction of the rib like structure.

In an example, the forming a rib like structure on the plastic encapsulation layer includes: forming the rib like structure; attaching the rib like structure to the top surface of the plastic encapsulation layer.

In an example, the forming a plastic encapsulation layer and forming a rib like structure on the plastic encapsulation layer includes: providing an injection mold; forming the plastic encapsulation layer and the rib like structure by injection molding with the injection mold.

In an example, a thermal expansion coefficient of a material of the rib like structure is less than that of a material of the plastic encapsulation layer.

In an example, a thermal expansion coefficient of a material of the plastic encapsulation layer ranges from 9 ppm/K to 36 ppm/K, and a thermal expansion coefficient of a material of the rib like structure ranges from 0.12 ppm/K to 0.18 ppm/K.

In an example, a thermal conductivity of a material of the rib like structure is greater than a preset value.

In an example, the preset value is 200 W/(m·K).

In the fourth aspect, the example of the present disclosure provides a forming method of a memory system including: providing a package substrate; disposing a chip on the package substrate; forming a plastic encapsulation layer covering the chip; forming a rib like structure on the plastic encapsulation layer, a bottom surface of the rib like structure being located on a top surface of the plastic encapsulation layer.

In an example, the rib like structure includes a rib like portion and a hollow portion, a bottom surface of the rib like portion is located on the top surface of the plastic encapsulation layer, and the hollow portion exposes the top surface of the plastic encapsulation layer.

In an example, the disposing a chip on the package substrate includes: disposing a memory chip and a controller chip arranged in a direction parallel to the package substrate on the package substrate. Forming a rib like structure on the plastic encapsulation layer includes: a ratio of an area of an orthographic projection of the rib like portion formed directly above the controller chip on the package substrate to an area of an orthographic projection of the rib like structure formed directly above the controller chip on the package substrate being a first ratio; a ratio of an area of an orthographic projection of the rib like portion formed directly above the memory chip on the package substrate to an area of an orthographic projection of the rib like structure formed directly above the memory chip on the package substrate being a second ratio, and the first ratio being greater than or equal to the second ratio.

In examples provided by the present disclosure, the package structure includes a rib like structure located on the top surface of the plastic encapsulation layer. In an example, the rib like structure includes a rib like portion and a hollow portion, the bottom surface of the rib like portion is located on the top surface of the plastic encapsulation layer, and the hollow portion exposes the top surface of the plastic encapsulation layer, which can increase the heat dissipation area of the surface of the package structure. In another example, the rib like structure can include materials with high thermal conductivity and low thermal expansion coefficient, which can improve the heat dissipation performance and warpage resistance ability of the package structure, so as to improve the reliability of the package structure.

### BRIEF DESCRIPTION OF THE DRAWINGS

FIG. 1 is a schematic diagram of a three-dimensional structure of the package structure provided by the example of the present disclosure.

FIG. 2 is a top view of the package structure provided by the example of the present disclosure.

FIG. 3 is a schematic diagram of a three-dimensional structure of the memory system provided by the example of the present disclosure.

FIG. 4 is a top view of the memory system provided by the example of the present disclosure.

FIG. 5 is a thermal simulation diagram of the memory system provided by the related technology.

FIG. 6 is a thermal simulation diagram of the memory system provided by the example of the present disclosure.

FIG. 7 is the warpage simulation diagram of the memory system provided by the related technology at room temperature.

FIG. 8 is a warpage simulation diagram of the memory system provided by the example of the present disclosure at room temperature.

FIG. 9 is the warpage simulation diagram of the memory system provided by the related technology under high temperature.

FIG. 10 is a warpage simulation diagram of the memory system provided by the example of the present disclosure under high temperature.

FIG. 11 is a top view of a memory system provided by another example of the present disclosure.

FIG. 12 is a flowchart of a forming method of a package structure provided by an example of the present disclosure.

FIG. 13 is a flowchart of a forming method of a memory system provided by an example of the present disclosure.

### DETAILED DESCRIPTION

Examples of the present disclosure will be described in more detail below with reference to the accompanying drawings. Although examples of the present disclosure are shown in the accompanying drawings, the present disclosure may be implemented in various forms and should not be limited by the examples set forth herein. These examples are provided to enable a more thorough understanding of the present disclosure and to convey the scope of the present disclosure to those skilled in the art.

In the following description, details are given in order to provide a more thorough understanding of the present disclosure. However, the present disclosure can be implemented without one or more of these details. In other examples, in order to avoid confusion with the present disclosure, some technical features known in the art are not described. For example, all features of the actual example are not described here, and the well-known functions and structures are not described in detail.

In the drawings, the same reference numerals denote the same elements throughout.

Spatial relationship terms such as “underneath,” “below,” “lower,” “under,” “over,” “upper” and so on can be used here for convenience of description to describe the relationship between one element or feature shown in the figure and other elements or features. In addition to the orientations shown in the figure, the spatial relationship term is intended to include different orientations of devices in use and operation. For example, if the device in the drawing is flipped, then the element or feature described as “below other elements” or “under it” or “underneath it” will be oriented to be “on” other elements or features. Therefore, the exemplary terms “below” and “underneath” may include two orientations, upper and lower. The device may be otherwise oriented (rotated 90 degrees or other orientation) and the spatial description terms used herein are interpreted accordingly.

The terms used herein are intended only to describe specific examples and are not intended to be a limitation of the present disclosure. When used herein, the singular forms of “a,” “an” and “said/the” are also intended to include the plural form, unless the context clearly indicates otherwise. The terms “consist of” and/or “including” when used in this specification determine the existence of the features, integers, steps, operations, elements and/or components, but do not exclude the existence or addition of one or more other features, integers, steps, operations, elements, components and/or groups. As used herein, the term “and/or” includes any and all combinations of the relevant listed items.

The semiconductor device includes a package substrate, a semiconductor chip disposed on the package substrate and a plastic encapsulation body covering the semiconductor chip. In practical applications, due to the thermal expansion coefficient of the plastic encapsulation material, when the ambient temperature changes dramatically, such as when the temperature rises or falls sharply, the plastic encapsulation body is prone to warpage deformation. This may lead to cracks in the semiconductor chip or delamination between the semiconductor chip and the package substrate and lead, and may further lead to the failure of the semiconductor device. In addition, due to the poor heat dissipation performance of the plastic encapsulation body, when the semiconductor device is in a high-power work state, the heat generated by the semiconductor chip cannot be transmitted outside the semiconductor device in time. This may lead to thermal failure or even spontaneous combustion of the semiconductor device. The above challenges will not only reduce the reliability of semiconductor devices, but also limit the application scenarios of semiconductor devices. Therefore, challenges exist in how to suppress the warpage deformation of semiconductor devices and improve the heat dissipation performance of semiconductor devices.

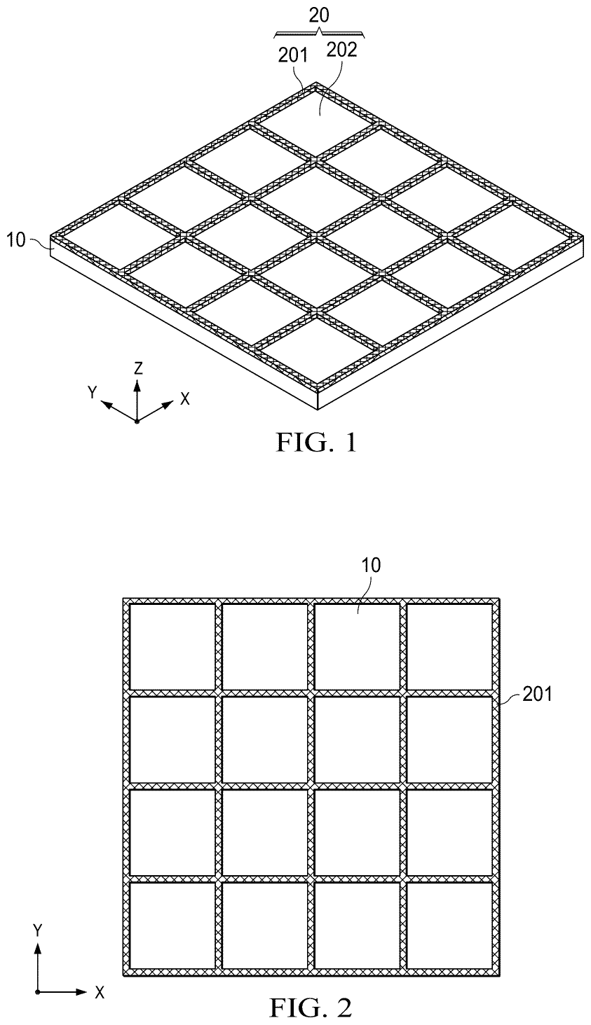

In this regard, an example of the present disclosure provides a package structure. FIG. 1 is a schematic diagram of a three-dimensional structure of the package structure, and FIG. 2 is a top view of the package structure. Referring to FIG. 1 and FIG. 2, the package structure includes: plastic encapsulation layer 10 and rib like structure 20. The rib like structure 20 is located on the plastic encapsulation layer 10, and the bottom surface of the rib like structure 20 is located on the top surface of the plastic encapsulation layer 10.

In some examples, the rib like structure 20 includes a rib like portion 201 and a hollow portion 202. A bottom surface of the rib like portion 201 is located on a top surface of the plastic encapsulation layer 10, and the hollow portion 202 exposes the top surface of the plastic encapsulation layer 10.

In the example of the present disclosure, the rib like portion 201 of the rib like structure 20 covers the top surface of the plastic encapsulation layer 10 in a rib like shape.

In some examples, the rib like portion 201 includes a plurality of portions extending in a first direction and a plurality of portions extending in a second direction. The first direction intersects the second direction, and both are perpendicular to the thickness direction of the rib like structure 20.

In the example of the present disclosure, the thickness direction of the rib like structure 20 is the Z direction.

In an example, referring to FIG. 2, the first direction is the X direction, the second direction is the Y direction, and the first direction is perpendicular to the second direction. The portions of the rib like portion 201 extending in the first direction cross with the portions extending in the second direction, and surround the hollow portion 202 which is a square in shape.

An example of the present disclosure illustrates the package structure by taking, as an example, the first direction as the X direction, the second direction as the Y direction, and the shape of the hollow portion 202 as a square, but the present disclosure is not limited to this. For example, the shape of the hollow portion 202 between the rib like portions 201 can also be one or more of a rectangle, a diamond, and a parallelogram.

In other examples, the shape of the hollow portion 202 between the rib like portions 201 may be one or more of triangles, irregular polygons, circles, ellipses, and rings.

In the example of the present disclosure, the rib like structure 20 includes a rib like portion 201 and a hollow portion 202. The bottom surface of the rib like portion 201 is located on the top surface of the plastic encapsulation layer 10, and the rib like portion 201 has a certain thickness. The hollow portion 202 exposes the top surface of the plastic encapsulation layer 10 and the side wall of the rib like portion 201. Therefore, the heat dissipation area of the upper surface of the package structure can be increased without changing the bottom surface area of the package structure, so as to improve the heat dissipation performance of the package structure.

In an example of the present disclosure, the upper surface of the package structure includes the top surface of the rib like portion 201, the top surface of the plastic encapsulation layer 10 exposed by the hollow portion 202, and the side wall of the rib like portion 201. The area of the side wall of the rib like portion 201 is the difference between the heat dissipation area of the upper surface of the package structure provided with the rib like structure 20 and the heat dissipation area of the upper surface of the package structure without the rib like structure 20 when the bottom area of the package structure remains unchanged.

In the example of the present disclosure, the thickness of the rib like structure can be set according to the specific requirements of chip warpage and heat dissipation. In an example, the greater the thickness of the rib like structure, the larger the heat dissipation area of the package structure, which can make the heat dissipation effect and warpage resistance effect of the package structure better. However, too large thickness will also make the material consumption of the rib like structure larger, and lead to the overall package structure being thicker, which is not conducive to the development trend of miniaturization of semiconductor devices. Therefore, the thickness of rib like structure is set according to heat dissipation, warpage, materials used, integration degree and other factors.

In some examples, without changing the thickness of the plastic encapsulation layer 10, a rib like structure 20 with a certain thickness can be set on the plastic encapsulation layer 10. In an example, the thickness of the package structure provided with the rib like structure 20 does not exceed the upper limit of the thickness design specification of the package structure, and a thickness is reserved for the subsequent wiring process. In other examples, the thickness of the plastic encapsulation layer 10 can be reduced to be used as the setting thickness of the rib like structure 20. For example, the rib like structure 20 can be set without changing the bottom area of the package structure or the thickness of the package structure, so as to improve the reliability of the package structure without affecting the integration of the package structure. The package structure provided by the present disclosure can have a variety of different application scenarios, and the design specifications of the package structure are different in different application scenarios. Therefore, the present disclosure has no specific restrictions on the thickness of the plastic encapsulation layer and the thickness of the rib like structure in the package structure. In practical application, the thickness of plastic encapsulation layer and that of the rib like structure can be set according to the specific application scenario and the design specification corresponding to the application scenario.

In some examples, the material of the rib like structure 20 is the same as that of the plastic encapsulation layer 10.

In some examples, the materials of the plastic encapsulation layer 10 and the rib like structure 20 are both plastic encapsulation materials. The plastic encapsulation materials can be epoxy resin molding compounds, including epoxy resin as a matrix, phenolic resin as a curing agent, silicon dioxide as a filler and various additives. The epoxy resin molding compound is only an example of the plastic encapsulation material, and the present disclosure does not limit the specific composition of the plastic encapsulation material.

In some examples, the material of the rib like structure 20 is different from that of the plastic encapsulation layer 10.

In some examples, the thermal expansion coefficient of the material of the rib like structure 20 is less than that of the material of the plastic encapsulation layer 10.

In some specific examples, the thermal expansion coefficient of the material of the plastic encapsulation layer 10 ranges from 9 ppm/K to 36 ppm/K, and the thermal expansion coefficient of the material of the rib like structure 20 ranges from 0.12 ppm/K to 0.18 ppm/K.

In the example of the present disclosure, the thermal expansion coefficient of the material of the rib like structure 20 is less than that of the material of the plastic encapsulation layer 10. When the ambient temperature changes, the shape change of the rib like structure 20 is less than that of the plastic encapsulation layer 10, and the rib like structure 20 covers the entire top surface of the plastic encapsulation layer 10 in a rib like shape, so as to reduce the degree of warpage deformation of the plastic encapsulation layer 10. In addition, at room temperature, when the package structure is bent, the rib like structure 20 can also play a role in dispersing the bending stress.

In some examples, the thermal conductivity of the material of the rib like structure 20 is greater than a preset value.

In some specific examples, the thermal conductivity of the material of the rib like structure 20 is greater than 200 W/(m·K), and the thermal conductivity of the material of the plastic encapsulation layer 10 ranges from 0.9 to 1.05 w/(m·K).

In the example of the present disclosure, the rib like structure 20 may include a material with a large thermal conductivity, and the thermal conductivity of the material of the rib like structure 20 is greater than that of the material of the plastic encapsulation layer 10. Therefore, the rib like structure 20 can not only increase the heat dissipation area of the upper surface of the package structure, but also improve the average thermal conductivity of the upper surface of the package structure, so that the heat generated in the package structure can be transmitted outside the package structure in time, so as to improve the heat dissipation performance of the package structure.

In some examples, the materials of the rib like structure 20 include but are not limited to: alloy materials, such as tungsten copper alloys; composite materials composed of metal materials and inorganic nonmetallic materials, such as composite materials composed of one or more of copper, silver and aluminum and one or more of diamond, pyrolytic graphite, carbon nanotubes, silicon, silicon dioxide, silicon carbide and aluminum nitride; composite materials composed of metal materials and organic polymers, such as composite materials composed of nano copper particles and epoxy resin.

In the example of the present disclosure, the rib like structure 20 provided on the plastic encapsulation layer 10 can include materials with high thermal conductivity and low thermal expansion coefficient. Therefore, the rib like structure 20 can not only enhance the heat dissipation performance of the package structure, but also inhibit the warpage deformation of the package structure, so as to improve the reliability of the package structure.

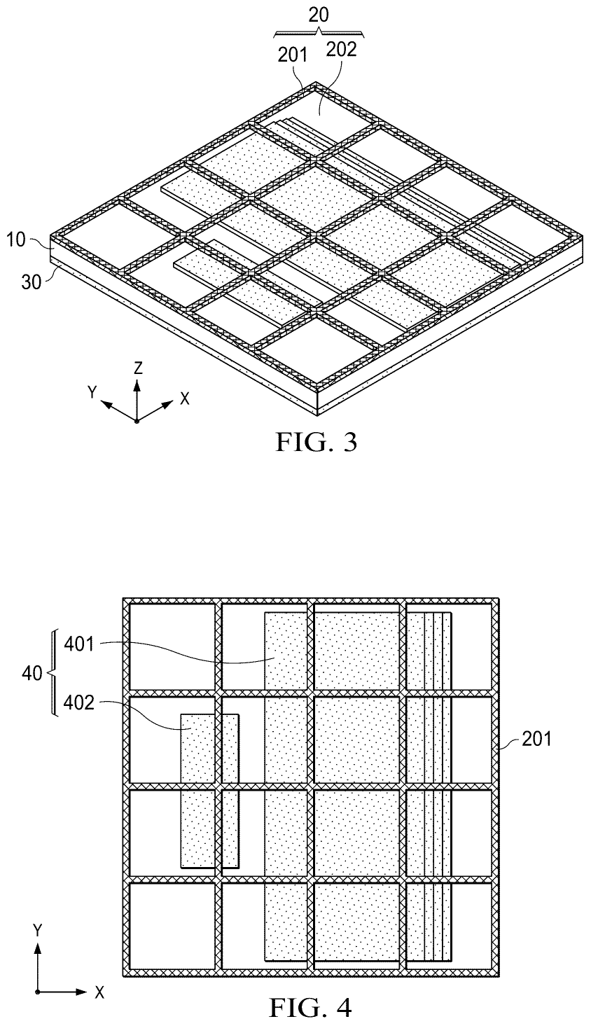

An example of the present disclosure provides a memory system. FIG. 3 and FIG. 4 are a schematic diagram and top view of the three-dimensional structure of the memory system, respectively. Referring to FIG. 3 and FIG. 4, the memory system includes: a package substrate 30, a chip 40, a plastic encapsulation layer 10 and a rib like structure 20. The chip 40 is located on the package substrate 30, the plastic encapsulation layer 10 covers the chip 40, the rib like structure 20 is located on the plastic encapsulation layer 10, and the bottom surface of the rib like structure 20 is located on the top surface of the plastic encapsulation layer 10. The plastic encapsulation layer 10 and the rib like structure 20 comprise the package structure in the above example.

For the convenience of observation, the plastic encapsulation layer 10 in FIG. 3 is in perspective.

In some examples, the chip 40 includes a memory chip 401 and a controller chip 402 arranged in the direction parallel to the package substrate 30. The memory chip 401 and the controller chip 402 are electrically connected through a wire (not shown in the figures.) or a circuit in the package substrate 30.

In some examples, the memory chip 401 includes a plurality of memory chips stacked in the Z direction, including at least one 3D NAND memory chip.

In some examples, the memory system can be one of compact flash card (CFC), smart media card (SMC), memory stick (MS), multi media card (MMC), such as RS-MMC, MMCmicro, EMMC, etc., secure digital memory card (SD card), such as mini SD card, micro SD card, SDHC card, etc., Universal flash storage (UFS) card and solid state drive (SSD).

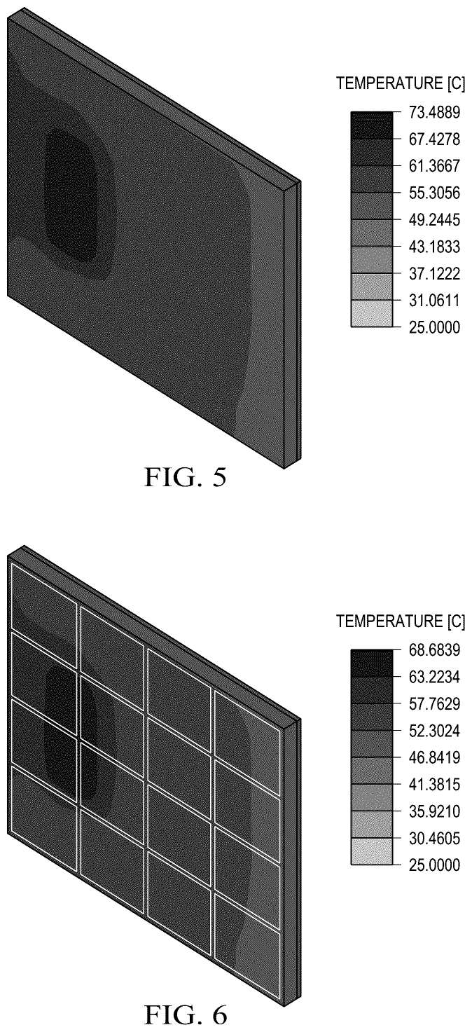

FIG. 5 and FIG. 6 are the thermal simulation results of the memory system provided by the related technology and the memory system provided by the example of the present disclosure, respectively. With reference to FIG. 5 and FIG. 6, under the same work environment, when the heat generation rate of the chip 40 is higher than the heat dissipation rate of the memory system, the temperature of the memory system will rise. The relatively high temperature sites of the two memory systems both correspond to the setting site of the controller chip 402, and the maximum temperature of the memory system provided with the rib like structure 20 in the example of the present disclosure is lower than that of the memory system provided without the rib like structure 20 in the related technology. For example, the memory system provided by the example of the present disclosure has higher heat dissipation rate and better heat dissipation performance.

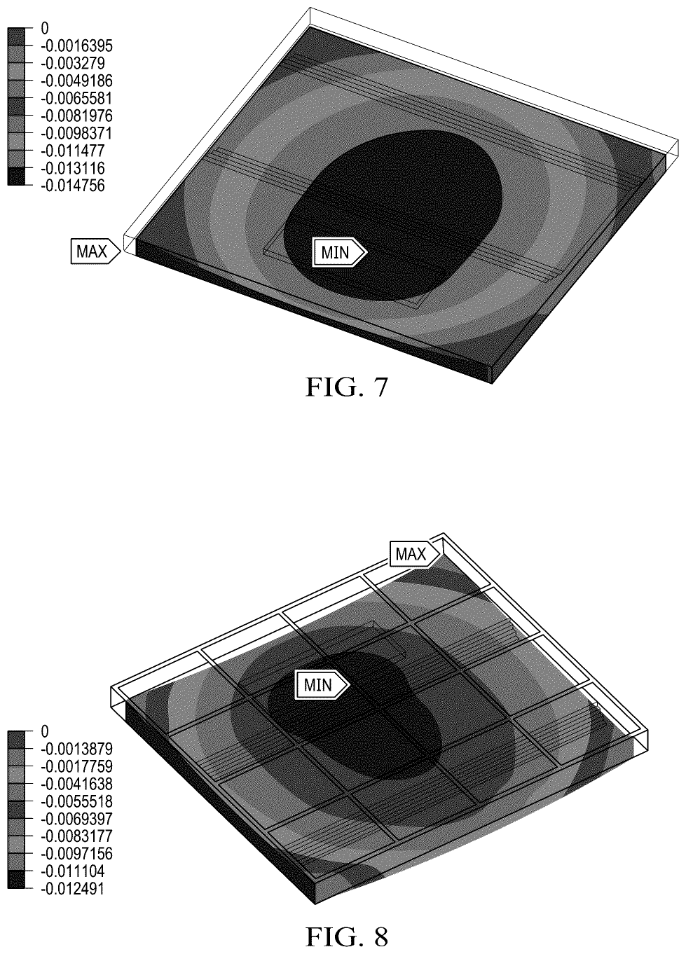

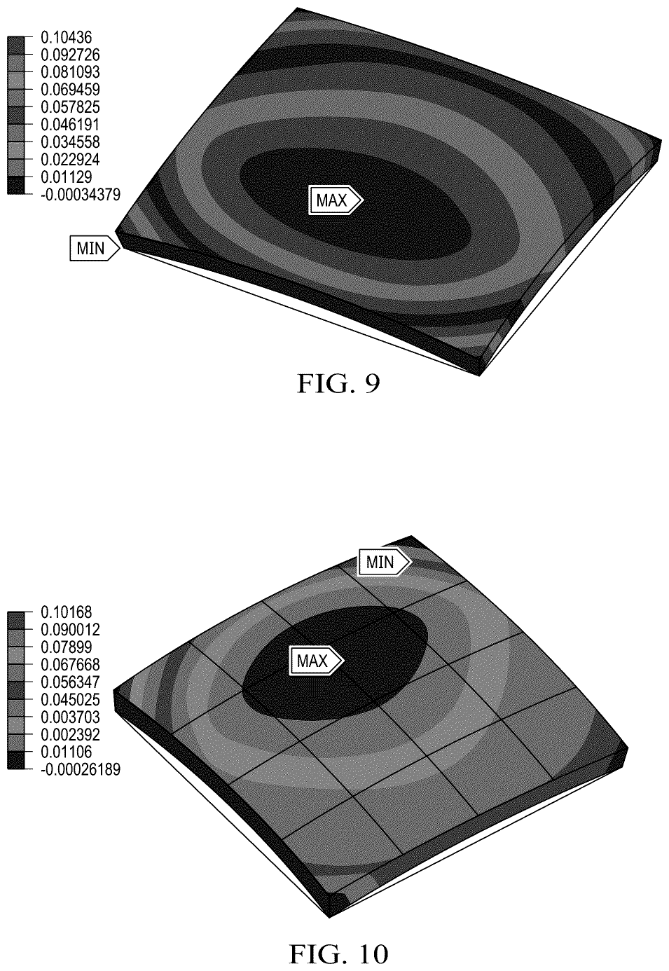

FIG. 7 and FIG. 8 respectively show the warpage simulation results of the memory system provided by the related technology and the memory system provided by the example of the present disclosure at room temperature. FIG. 9 and FIG. 10 respectively show the warpage simulation results of the memory system provided by the related technology and the memory system provided by the example of the present disclosure at high temperature. Referring to FIG. 7 and FIG. 8, at room temperature, the central site of the memory system is concave downward relative to the four corners, and the warpage degree of the memory system with the rib like structure 20 is less than that of the memory system without the rib like structure 20. Referring to FIG. 9 and FIG. 10, at high temperature, the central site of the memory system is convex upward relative to the four corners, and the warpage degree of the memory system with the rib like structure 20 is less than that of the memory system without the rib like structure 20. The warpage degree of the memory system can be expressed by the difference between the maximum warpage height and the minimum warpage height of the memory system.

To provide reliability of the simulation test results, the difference between the memory system provided by the related technology and the memory system provided by the example of the present disclosure is only in that the plastic encapsulation layer 10 of the memory system provided by the example of the present disclosure is provided with a rib like structure 20.

According to the above simulation test results, the memory system provided with the rib like structure 20 in the example of the present disclosure has better heat dissipation performance and higher warpage resistance ability than the memory system in the related technology. For example, the rib like structure 20 can improve the reliability of the memory system.

In some examples, the ratio of the area of the orthographic projection of the rib like portion 201 directly above the controller chip 402 on the package substrate 30 to the area of the orthographic projection of the rib like structure 20 directly above the controller chip 402 on the package substrate 30 is a first ratio, and the ratio of the area of the orthographic projection of the rib like portion 201 directly above the memory chip 401 on the package substrate 30 to the area of the orthographic projection of the rib like structure 20 directly above the memory chip 401 on the package substrate 30 is a second ratio.

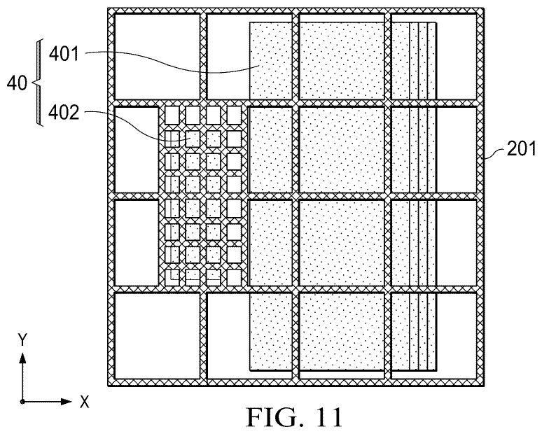

In some examples, referring to FIG. 4, the first ratio is equal to the second ratio. In other examples, referring to FIG. 11, the first ratio is greater than the second ratio. For example, the rib like structure 20 may be locally condensed. Based on the thermal simulation results shown in FIG. 5 and FIG. 6, in the memory system the heat production of the controller chip 402 is generally higher than that of the memory chip 401. The rib like structure 20 locally condensed can improve the heat dissipation performance of the package structure directly above the controller chip 402, so that the memory system has higher reliability.

In the example of the present disclosure, the rib like structure 20 of the corresponding area can be adaptively adjusted according to the different heat production corresponding to different areas of the memory system, so as to further improve the heat dissipation performance of the memory system.

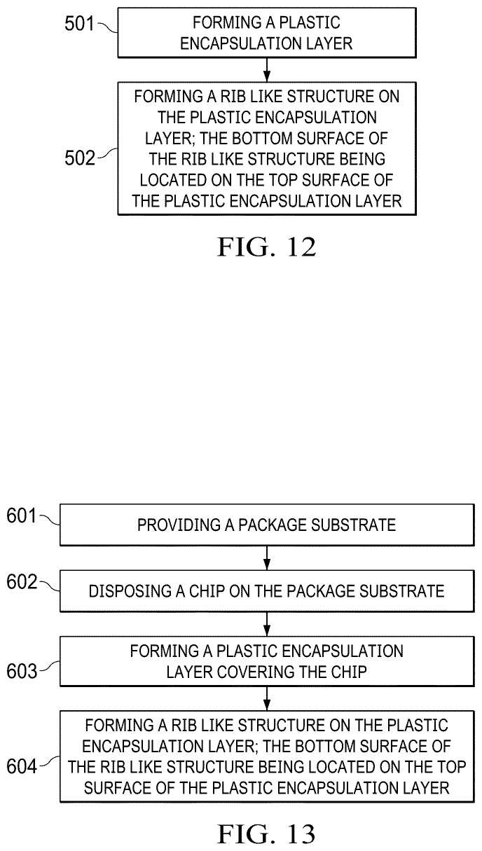

In the above example, the example of the present disclosure provides a forming method of a package structure. FIG. 12 is a flowchart of a forming method of a package structure. The forming method of a package structure includes the following operations:

Operation 501: forming a plastic encapsulation layer;

Operation 502: forming a rib like structure on the plastic encapsulation layer; the bottom surface of the rib like structure being located on the top surface of the plastic encapsulation layer.

FIG. 1 and FIG. 2 are respectively a schematic diagram and a top view of a three-dimensional structure of the package structure obtained by the forming method of the package structure shown in FIG. 12. The rib like structure 20 includes a rib like portion 201 and a hollow portion 202. The bottom surface of the rib like portion 201 is located on the top surface of the plastic encapsulation layer 10, and the hollow portion 202 exposes the top surface of the plastic encapsulation layer 10.

In the example of the present disclosure, the rib like portion 201 of the rib like structure 20 covers the top surface of the plastic encapsulation layer 10 in a rib like shape.

In some examples, the rib like portion 201 includes a plurality of portions extending in the first direction and a plurality of portions extending in the second direction. The first direction intersects with the second direction, and both are perpendicular to the thickness direction of the rib like structure 20.

In the example of the present disclosure, the thickness direction of the rib like structure 20 is the Z direction.

In an example, the first direction is the X direction, the second direction is the Y direction, and the first direction is perpendicular to the second direction. The portion of the rib like portion 201 extending in the first direction and the portion extending in the second direction cross with each other and surround the hollow portion 202 which is a square in shape.

The example of the present disclosure illustrates the package structure by taking the first direction as the X direction, the second direction as the Y direction, and the shape of the hollow portion 202 as a square, but the present disclosure is not limited to this. For example, the hollow portion 202 between the rib like portions 201 can also be formed as one or more of the quadrilaterals such as a rectangle, a diamond, a parallelogram, etc.

In other examples, the hollow portion 202 between the rib like portions 201 may be formed as one or more of triangles, irregular polygons, circles, ellipses, and rings.

In the example of the present disclosure, a rib like structure 20 is formed on the top surface of the plastic encapsulation layer 10. The rib like structure 20 includes a rib like portion 201 and a hollow portion 202. The bottom surface of the rib like portion 201 is located on the top surface of the plastic encapsulation layer 10, and the rib like portion 201 has a certain thickness. The hollow portion 202 exposes the top surface of the plastic encapsulation layer 10 and the side wall of the rib like portion 201. Therefore, the heat dissipation area of the upper surface of the package structure can be increased without changing the bottom surface area of the package structure, improving the heat dissipation performance of the package structure.

In the example of the present disclosure, the thickness of the rib like structure can be set according to the specific requirements of chip warpage and heat dissipation. The larger the thickness of the rib like structure, the larger the heat dissipation area of the package structure, which can improve the heat dissipation effect and warpage resistance effect of the package structure. However, too large thickness will also make the material consumption of the rib like structure larger, and increase the overall package structure thicker, which is not conducive to the development trend of miniaturization of semiconductor devices. Therefore, the thickness of rib like structure is set according to heat dissipation, warpage, materials used, integration degree and other factors.

In some examples, a rib like structure 20 with a certain thickness can be formed on the plastic encapsulation layer 10 without changing the thickness of the plastic encapsulation layer 10. The thickness of the package structure provided with the rib like structure 20 should not exceed the upper limit of the thickness design specification of the package structure, and a thickness should be reserved for the subsequent wiring process. In other examples, the thickness of the plastic encapsulation layer 10 can be appropriately reduced to be used as the setting thickness of the rib like structure 20. For example, the rib like structure 20 can be formed without changing the bottom area of the package structure or the thickness of the package structure, so as to improve the reliability of the package structure without affecting the integration of the package structure.

In some examples, the process of performing operation 502 is: forming a rib like structure 20; attaching the rib like structure 20 to the top surface of the plastic encapsulation layer 10.

In the example of the present disclosure, the plastic encapsulation layer 10 and the rib like structure 20 can be formed respectively, and the process operation s of forming the plastic encapsulation layer 10 can be carried out successively or simultaneously with the process operation s of forming the rib like structure 20.

In some examples, the rib like structure 20 is formed using the same material as that of the plastic encapsulation layer 10.

In some examples, the materials of the plastic encapsulation layer 10 and the rib like structure 20 are both plastic encapsulation materials. The plastic encapsulation materials can be epoxy resin molding compounds, including epoxy resin as a matrix, phenolic resin as a curing agent, silicon dioxide as a filler, and various additives. The epoxy resin molding compound is only an example of the plastic encapsulation material, and the present disclosure does not limit the specific composition of the plastic encapsulation material.

In some examples, the rib like structure 20 is formed using a material different from the material of the plastic encapsulation layer 10.

In some examples, the thermal expansion coefficient of the material of the rib like structure 20 is less than that of the material of the plastic encapsulation layer 10.

In some examples, the thermal expansion coefficient of the material of the plastic encapsulation layer 10 ranges from 9 ppm/K to 36 ppm/K, and the thermal expansion coefficient of the material of the rib like structure 20 ranges from 0.12 ppm/K to 0.18 ppm/K.

In the example of the present disclosure, the thermal expansion coefficient of the material of the rib like structure 20 is less than that of the material of the plastic encapsulation layer 10. When the ambient temperature changes, the shape change of the rib like structure 20 is less than that of the plastic encapsulation layer 10, and the rib like structure 20 covers the entire top surface of the plastic encapsulation layer 10 in the rib like shape, so as to reduce the degree of warpage deformation of the plastic encapsulation layer 10. In addition, at room temperature, when the package structure is bent, the rib like structure 20 can also play a role in dispersing the bending stress.

In some examples, the thermal conductivity of the material of the rib like structure 20 is greater than a preset value.

In some specific examples, the thermal conductivity of the material of the rib like structure 20 is greater than 200 W/(m·K), and the thermal conductivity of the material of the plastic encapsulation layer 10 ranges from 0.9 to 1.05 w/(m·K).

In the example of the present disclosure, a material with a large thermal conductivity can be configured to form a rib like structure 20, and the thermal conductivity of the material of the rib like structure 20 is greater than that of the material of the plastic encapsulation layer 10. Therefore, the rib like structure 20 can not only increase the heat dissipation area of the upper surface of the package structure, but also increase the average thermal conductivity of the upper surface of the package structure, so as to improve the heat dissipation performance of the package structure.

In some examples, the materials of the rib like structure 20 include but are not limited to: alloy materials, such as tungsten copper alloys; composite materials composed of metal materials and inorganic nonmetallic materials, such as composite materials composed of one or more of copper, silver and aluminum and one or more of diamond, pyrolytic graphite, carbon nanotubes, silicon, silicon dioxide, silicon carbide and aluminum nitride; composite materials composed of metal materials and organic polymers, such as composite materials composed of copper nanoparticles and epoxy resin.

In the example of the present disclosure, the rib like structure 20 and the plastic encapsulation layer 10 are formed respectively. The rib like structure 20 can be formed by using materials with both high thermal conductivity and low thermal expansion coefficient. Thus, not only can the heat dissipation performance of the package structure be enhanced, but also can the warpage deformation of the package structure be suppressed, so as to effectively improve the reliability of the package structure.

In some examples, the process of performing operation 501 and operation 502 is:

providing an injection mold; forming the plastic encapsulation layer 10 and the rib like structure 20 by injection molding with an injection mold. For example, an injection mold including a pattern of the rib like structure 20 can be formed first, and then the plastic encapsulation layer 10 and the rib like structure 20 can be formed by injection molding with the injection mold.

In some examples, the same material as that of the plastic encapsulation layer 10 is configured to form the rib like structure 20. For example, during the injection molding process, the same plastic encapsulation material is configured to form the plastic encapsulation layer 10 and the rib like structure 20, so that the plastic encapsulation layer 10 and the rib like structure 20 are formed as one. Thus, the heat dissipation performance and warpage resistance ability of the package structure can be increased without changing the package structure forming material.

In other examples, the rib like structure 20 is formed using a material different from the material of the plastic encapsulation layer 10. For example, the portion corresponding to the plastic encapsulation layer 10 in the injection mold can be injected with one plastic encapsulation material, and then the portion corresponding to the rib like structure 20 in the injection mold can be injected with another plastic encapsulation material. For example, the plastic encapsulation material containing metal nanoparticles can be configured to inject the portion corresponding to the rib like structure 20 in the injection mold. The thermal conductivity of the metal nanoparticles is high, which can improve the thermal conductivity of the portion of the material of the rib like structure 20, so as to further improve the heat dissipation performance of the package structure.

In an example, the present disclosure provides a forming method of a memory system. FIG. 13 is a flowchart of a forming method of a memory system, which includes the following operations:

Operation 601: providing a package substrate;

Operation 602: disposing a chip on the package substrate;

Operation 603: forming a plastic encapsulation layer covering the chip; and

Operation 604: forming a rib like structure on the plastic encapsulation layer; the bottom surface of the rib like structure being located on the top surface of the plastic encapsulation layer.

In some examples, FIG. 3 and FIG. 4 are respectively a schematic diagram and a top view of a three-dimensional structure of the memory system obtained by the memory system forming method shown in FIG. 13. The rib like structure 20 includes a rib like portion 201 and a hollow portion 202. The bottom surface of the rib like portion 201 is located on the top surface of the plastic encapsulation layer 10, and the hollow portion 202 exposes the top surface of the plastic encapsulation layer 10.

In some examples, a chip 40 is provided on the package substrate 30. An example process is as follows: a memory chip 401 and a controller chip 402 arranged in a direction parallel to the package substrate 30 being disposed on the package substrate 30.

In some examples, the ratio of the area of the orthographic projection of the rib like portion 201 formed directly above the controller chip 402 on the package substrate 30 to the area of the orthographic projection of the rib like structure 20 formed directly above the controller chip 402 on the package substrate 30 is a first ratio. The ratio of the area of the orthographic projection of the rib like portion 201 formed directly above the memory chip 401 on the package substrate 30 to the area of the orthographic projection of the rib like structure 20 formed directly above the memory chip 401 on the package substrate 30 is a second ratio.

In some examples, referring to FIG. 4, the first ratio is equal to the second ratio. In other examples, referring to FIG. 11, the first ratio is greater than the second ratio. For example, in the process of forming the rib like structure 20, the rib like structure 20 can be locally condensed according to the arrangement of chips in the memory system. Using the rib like structure 20 locally condensed can improve the heat dissipation performance of the package structure directly above the controller chip 402, so that the memory system has higher reliability.

In the example of the present disclosure, the rib like structure of the corresponding area can be adjusted according to the different heat production corresponding to different areas of the memory system, so as to further improve the heat dissipation performance of the memory system.

The example of the present disclosure provides a package structure with high heat dissipation performance and warpage resistance ability and a memory system including the package structure.

In the example of the present disclosure, the package structure includes a rib like structure located on the plastic encapsulation layer, and the rib like structure includes a rib like portion and a hollow portion. The bottom surface of the rib like portion is located on the top surface of the plastic encapsulation layer, the rib like portion has a certain thickness. The hollow portion exposes the top surface of the plastic encapsulation layer and the side wall of the rib like portion, so that the package structure can have a large heat dissipation area while keeping the bottom area unchanged.

In the example of the present disclosure, the rib like structure can include materials with large thermal conductivity, which can improve the average thermal conductivity of the upper surface of the package structure, increase the heat dissipation rate of the memory system, and reduce the risk of thermal failure of the memory system.

In the example of the present disclosure, the rib like structure can include a material with a small thermal expansion coefficient, and the rib like portion covers the entire top surface of the plastic encapsulation layer in a rib like shape. This can not only reduce the degree of warpage deformation of the plastic encapsulation layer when the temperature changes, but also disperse the bending stress when the memory system is bent, so as to improve the warpage resistance ability of the memory system, reduce the risk of chip cracks in the memory system or delamination between the semiconductor chip and the package substrate and lead.

The features disclosed in several device examples provided by the present disclosure can be arbitrarily combined to obtain new device examples without conflict.

The methods disclosed in several method examples provided by the present disclosure can be arbitrarily combined to obtain new method examples without conflict.

The above is only the specific implementation of the present disclosure, but the scope of protection of the present disclosure is not limited to this. Any of those skilled in the art can easily think of changes or replacements within the scope of the disclosure, which should be included in the scope of protection of the present disclosure. Therefore, the scope of protection of the present disclosure shall be defined by the scope of protection of the claims.

What is claimed is:

1. A package structure, comprising:
a plastic encapsulation layer; and
a rib like structure located on the plastic encapsulation layer, wherein a bottom surface of the rib like structure is located on a top surface of the plastic encapsulation layer.

2. The package structure according to claim 1, wherein the rib like structure includes a rib like portion and a hollow portion, a bottom surface of the rib like portion is located on the top surface of the plastic encapsulation layer, and the hollow portion exposes the top surface of the plastic encapsulation layer.

3. The package structure according to claim 2, wherein the rib like portion includes a plurality of portions extending along a first direction and a plurality of portions extending along a second direction, the first direction intersects the second direction, and both are perpendicular to a thickness direction of the rib like structure.

4. The package structure according to claim 1, wherein a material of the rib like structure is the same as that of the plastic encapsulation layer.

5. The package structure according to claim 1, wherein a material of the rib like structure is different from that of the plastic encapsulation layer.

6. The package structure according to claim 1, wherein a thermal expansion coefficient of a material of the rib like structure is less than that of a material of the plastic encapsulation layer.

7. The package structure according to claim 1, wherein a thermal expansion coefficient of a material of the plastic encapsulation layer ranges from 9 ppm/K to 36 ppm/K, and a thermal expansion coefficient of a material of the rib like structure ranges from 0.12 ppm/K to 0.18 ppm/K.

8. The package structure according to claim 1, wherein a thermal conductivity of a material of the rib like structure is greater than 200 W/(m·K).

9. A memory system, comprising:
a package substrate;
a chip located on the package substrate;
a plastic encapsulation layer covering the chip; and
a rib like structure located on the plastic encapsulation layer, wherein a bottom surface of the rib like structure is located on a top surface of the plastic encapsulation layer.

10. The memory system according to claim 9, wherein the rib like structure includes a rib like portion and a hollow portion, a bottom surface of the rib like portion is located on the top surface of the plastic encapsulation layer, and the hollow portion exposes the top surface of the plastic encapsulation layer.

11. The memory system according to claim 10, wherein the chip includes a memory chip and a controller chip arranged in a direction parallel to the package substrate,
a ratio of an area of an orthographic projection of the rib like portion directly above the controller chip on the package substrate to an area of an orthographic projection of the rib like structure directly above the controller chip on the package substrate is a first ratio,
a ratio of an area of an orthographic projection of the rib like portion directly above the memory chip on the package substrate to an area of an orthographic projection of the rib like structure directly above the memory chip on the package substrate is a second ratio, and
the first ratio is greater than or equal to the second ratio.

12. The memory system according to claim 11, wherein the memory chip includes a three-dimensional NAND memory chip.

13. A forming method of a package structure, comprising:
forming a plastic encapsulation layer; and
forming a rib like structure on the plastic encapsulation layer, a bottom surface of the rib like structure being located on a top surface of the plastic encapsulation layer.

14. The forming method of claim 13, wherein the rib like structure includes a rib like portion and a hollow portion, a bottom surface of the rib like portion is located on the top surface of the plastic encapsulation layer, and the hollow portion exposes the top surface of the plastic encapsulation layer.

15. The forming method of claim 14, wherein the rib like portion includes a plurality of portions extending along a first direction and a plurality of portions extending along a second direction, the first direction intersects the second direction, and both are perpendicular to a thickness direction of the rib like structure.

16. The forming method of claim 13, wherein forming a rib like structure on the plastic encapsulation layer includes:
forming the rib like structure; and
attaching the rib like structure to the top surface of the plastic encapsulation layer.

17. The forming method of claim 13, wherein forming a plastic encapsulation layer and forming a rib like structure on the plastic encapsulation layer includes:
providing an injection mold; and
forming the plastic encapsulation layer and the rib like structure by injection molding with the injection mold.

18. The forming method of claim 13, wherein a thermal expansion coefficient of a material of the rib like structure is less than that of a material of the plastic encapsulation layer.

19. The forming method of claim 13, wherein a thermal expansion coefficient of a material of the plastic encapsulation layer ranges from 9 ppm/K to 36 ppm/K, and a thermal expansion coefficient of a material of the rib like structure ranges from 0.12 ppm/K to 0.18 ppm/K.

20. The forming method of claim 13, wherein a thermal conductivity of a material of the rib like structure is greater than 200 W/(m·K).
